(19) United States
(12) Patent Application Publication
(10) Pub. No.: US 2026/0251691 A1
(43) Pub. Date: Aug. 27, 2026

(54) DYNAMIC ON-RESISTANCE MEASUREMENT CIRCUIT

(71) Applicants: Materials Analysis Technology Inc., Hsinchu County (TW); National Yang Ming Chiao Tung University, Hsinchu City (TW)

(72) Inventors: Rustam Kumar, Bihar (IN); Tian-Li WU, Hsinchu City (TW); HUNG-JEN CHEN, Hsinchu City (TW)

(21) Appl. No.: 19/546,442

(22) Filed: Feb. 23, 2026

(51) Int. Cl. G01R 31/26; G01R 27/08

(52) U.S. Cl. CPC G01R 31/2621; G01R 27/08

(57) ABSTRACT

In a dynamic on-resistance measurement circuit, a control circuit is configured to, in an initial de-stressing process, sequentially turn on only a second switch to release a residual stress voltage of a tested transistor through the second switch while an energy storage circuit stores a common voltage; in a stress voltage applying process, turn off the second switch, and turn on a third switch and a first switch to apply a stress voltage to the tested transistor; and in a measurement procedure, turn off the first switch and the third switch, and turn on the tested transistor and the second switch such that a constant current flows through the second switch and an inductor to the tested transistor, and measure a voltage and a current of the tested transistor and accordingly calculate dynamic on-resistance of the tested transistor.

### CROSS-REFERENCE TO RELATED PATENT APPLICATION

This application claims the benefit of priority to Taiwan Patent Application No. 114106690, filed on February 24, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to dynamic on-resistance, and more particularly to a dynamic on-resistance measurement circuit.

### BACKGROUND OF THE DISCLOSURE

Group III–V power field-effect transistors (III–V FETs), such as gallium nitride (GaN) transistors, aluminum nitride (AlN) transistors and aluminum gallium nitride (AlGaN) transistors, have been widely used in power electronics, including renewable energy power conversion, data center power supplies, consumer electronics, and electric vehicles, due to high switching speed, low on-resistance, and excellent transconductance characteristics. Compared with conventional silicon (Si) devices, the III–V FETs provide higher power density and conversion efficiency. However, the dynamic on-resistance (which can be expressed as Rds, on) of the III–V FET varies with time and bias conditions. Accurate measurement of the dynamic on-resistance is important for power efficiency and thermal design.

Traditionally, the dynamic on-resistance characteristics of III–V FETs are usually estimated using a time-constant model, with model parameters extracted through a double pulse test (DPT). In the DPT, a device under test (DUT) is usually turned on to simulate switch behavior under actual operation by a first pulse, and a critical measurement is performed during a second pulse to evaluate the dynamic on-resistance. However, the existing techniques suffer from several problems, including an inability to control blocking time, an inability to independently adjust measurement parameters, and measurements occurring in a second current rising procedure, resulting in inaccurate model parameters.

In addition, commercial measurement equipment is usually unable to completely simulate real hard-switching conditions, and measurement results are easily affected by voltage and load conditions. Although improved measurement operations may enhance sensitivity or add current control, the measurement results are still be affected by voltage/current coupling, or require additional components, thereby increasing measurement complexity and delay. Therefore, a method capable of accurately and controllably measuring the dynamic on-resistance of III–V field-effect transistors, under real hard-switching conditions, is still lacking in the relevant art, which limits evaluation of power conversion efficiency and reliability.

### SUMMARY OF THE DISCLOSURE

In response to the above-referenced technical inadequacies, the present disclosure provides a dynamic on-resistance measurement circuit. The dynamic on-resistance measurement circuit is used for measuring a tested transistor. The dynamic on-resistance measurement circuit includes an energy storage circuit, a plurality of switch components, and a control circuit. The energy storage circuit is connected to a common power source and connected between a first discharge node and a second discharge node. The plurality of switch components include a first switch, a second switch and a third switch. A first terminal of the first switch is connected to the first discharge node. A first terminal of the third switch is connected to the second discharge node. A second terminal of the first switch is connected to a first terminal of the second switch and a first terminal of an inductor. A first terminal of the tested transistor is connected to a second terminal of the third switch and to a second terminal of the inductor. A second terminal of the second switch and a second terminal of the tested transistor are connected to a reference potential terminal. The control circuit is connected to a control terminal of each of the plurality of switch components. The control circuit is configured to perform a single measurement operation including, sequentially: in an initial de-stressing procedure, turning on only the second switch, such that a residual stress voltage of the tested transistor is released through the second switch; in a stress voltage applying procedure, turning off the second switch and turning on the third switch and the first switch, such that a stress voltage is applied across the first terminal and the second terminal of the tested transistor; and in a measurement procedure, turning off the first switch and the third switch and turning on the tested transistor and the second switch, measuring a voltage and a current between the first terminal and the second terminal of the tested transistor, and calculating a dynamic on-resistance of the tested transistor according to the voltage and the current.

In one of the possible or preferred embodiments, in the measurement procedure, the current is maintained at a stress current value to form a constant current.

In one of the possible or preferred embodiments, the control circuit is further configured to perform a stress voltage preparation procedure by first turning on the third switch after performing the initial de-stressing procedure and before the stress voltage applying procedure.

In one of the possible or preferred embodiments, the control circuit is further configured to: perform a first releasing procedure by turning off the tested transistor and turning on the third switch to reduce the current, after the measurement procedure is performed.

In one of the possible or preferred embodiments, the control circuit is further configured to perform a second releasing procedure by turning on the tested transistor to reduce the current to zero, after the first releasing procedure is performed.

In one of the possible or preferred embodiments, the energy storage circuit includes an energy storage capacitor connected between the first discharge node and the second discharge node and connected to the common power source.

In one of the possible or preferred embodiments, the dynamic on-resistance measurement circuit further includes an input power supply circuit. The input power supply circuit is connected to the first terminal of the third switch. The input power supply circuit is configured to supply an input voltage to the first terminal of the third switch.

In one of the possible or preferred embodiments, the input power supply circuit includes an input capacitor and an input power source. A first terminal of the input capacitor is connected to the first terminal of the third switch. A second terminal of the input capacitor is connected to the second terminal of the tested transistor and the second terminal of the second switch. The input power source is connected to the input capacitor and configured to supply input power to the input capacitor. The capacitor is configured to store the input power and discharges to the first terminal of the third switch.

In one of the possible or preferred embodiments, the tested transistor is a III–V group field-effect transistor.

In one of the possible or preferred embodiments, the tested transistor is a gallium nitride transistor, an aluminum nitride transistor, or an aluminum gallium nitride transistor.

In order to solve the above-mentioned problems, one of the technical aspects adopted by the present disclosure is to provide a dynamic on-resistance measurement circuit, which is used for measuring a tested transistor. The energy storage circuit is connected to a common power source and connected between a first discharge node and a second discharge node. The plurality of switch components includes a first switch, a second switch, and a third switch. A first terminal of the first switch is connected to the first discharge node. A first terminal of the third switch is connected to the second discharge node. A second terminal of the first switch is connected to a first terminal of the second switch and a first terminal of an inductor. A first terminal of the tested transistor is connected to a second terminal of the third switch and a second terminal of the inductor. A second terminal of the second switch and a second terminal of the tested transistor are connected to a reference potential terminal. The control circuit is connected to the control terminal of each of the plurality of switch components. The control circuit is configured to perform a continuous measurement operation multiple times. The continuous measurement operation includes, sequentially: in a stress voltage applying procedure, turning on the third switch and the first switch to apply a stress voltage across the first terminal and the second terminal of the tested transistor; in a measurement procedure, turning off the third switch and the first switch and turning on the tested transistor and the second switch, measuring a voltage and a current between the first terminal and the second terminal of the tested transistor, and calculating a dynamic on-resistance of the tested transistor according to the voltage and the current; and in a releasing procedure, continually turning on the second switch, turning on the third switch and turning off the tested transistor, such that the current flows through the third switch, the inductor, and the tested transistor to the reference potential terminal for releasing.

In one of the possible or preferred embodiments, in the continuous measurement operation, a duration of the releasing procedure is smaller than a duration of the measurement procedure.

In one of the possible or preferred embodiments, in the continuous measurement operation, a duration of the releasing procedure is smaller than a duration of the stress voltage applying procedure.

In one of the possible or preferred embodiments, the energy storage circuit includes an energy storage capacitor. The energy storage capacitor is connected between a first terminal of the first switch and the first terminal of the third switch, and connected to the common power source.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a dynamic on-resistance measurement circuit according to a first embodiment of the present disclosure;

FIG. 2 is a circuit diagram of a dynamic on-resistance measurement circuit according to a second embodiment of the present disclosure;

FIG. 3 is a flowchart diagram of a multi-stage procedure included in a single measurement operation of the dynamic on-resistance measurement circuit according to the first and second embodiments of the present disclosure;

FIG. 4 is a flowchart diagram of specific processes in the multi-stage procedure included in the single measurement operation performed by the dynamic on-resistance measurement circuit according to the first and second embodiments of the present disclosure;

FIG. 5 is a schematic diagram of a plurality of switch components of the dynamic on-resistance measurement circuit being switched according to the second embodiment of the present disclosure;

FIG. 6 is a schematic diagram of the plurality of switch components of the dynamic on-resistance measurement circuit being switched according to the second embodiment of the present disclosure;

FIG. 7 is a schematic diagram of the plurality of switch components of the dynamic on-resistance measurement circuit being switched according to the second embodiment of the present disclosure;

FIG. 8 is a schematic diagram of the plurality of switch components of the dynamic on-resistance measurement circuit being switched according to the second embodiment of the present disclosure;

FIG. 9 is a waveform diagram of a plurality of signals of the dynamic on-resistance measurement circuit according to the first and second embodiments of the present disclosure;

FIG. 10 is a flowchart diagram of a multi-stage procedure included in a continuous measurement operation performed by the dynamic on-resistance measurement circuit according to the first and second embodiments of the present disclosure;

FIG. 11 is a flowchart diagram of specific processes in the multi-stage procedure included in the continuous measurement operations of the dynamic on-resistance measurement circuit according to the first and second embodiments of the present disclosure;

FIG. 12 is a schematic diagram of the plurality of switch components of the dynamic on-resistance measurement circuit being switched according to the second embodiment of the present disclosure;

FIG. 13 is a schematic diagram of the plurality of switch components of the dynamic on-resistance measurement circuit being switched according to the second embodiment of the present disclosure; and

FIG. 14 is a waveform diagram of signals of the dynamic on-resistance measurement circuit according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

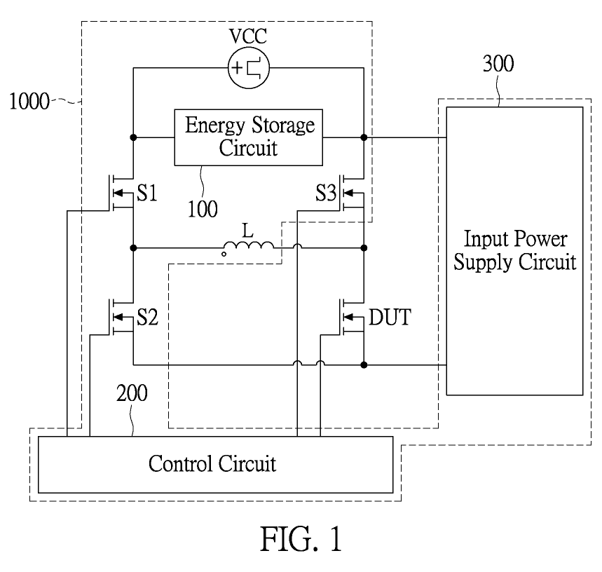

Reference is made to FIG. 1, which is a circuit diagram of a dynamic on-resistance measurement circuit according to a first embodiment of the present disclosure.

The present disclosure provides a dynamic on-resistance measurement circuit 1000, which is used for measuring dynamic on-resistance of a tested transistor DUT. In particular, the tested transistor DUT may be a Group III–V field-effect transistor, for example, which is made of gallium nitride, aluminum nitride, or aluminum gallium nitride. The Group III–V field-effect transistor has the characteristics of high-speed switching and low on-resistance, and has dynamic on-resistance that varies with bias conditions over time. Conventional measurement methods struggle to accurately capture these characteristics under real operating conditions. Therefore, the dynamic on-resistance measurement circuit 1000 provided by the present disclosure utilizes an innovative circuit configuration and an innovative measurement method to accurately measure the dynamic on-resistance of the tested transistor DUT that is the Group III–V field-effect transistor or a transistor made of another material, thereby accurately analyzing the dynamic conduction characteristics to meet requirements of high-efficiency power conversion and reliability.

To achieve the above objectives, the dynamic on-resistance measurement circuit 1000 of the present disclosure is connected to a first terminal, a second terminal and a control terminal of the tested transistor DUT. In particular, the dynamic on-resistance measurement circuit 1000 includes a plurality of switch components (including a first switch S1, a second switch S2, and a third switch S3 as shown in FIG. 1), which, together with the tested transistor DUT, form a symmetrical bridge structure (such as an H-bridge configuration). By turning on and off these switch components, current directions and voltage paths can be flexibly alternated in a multi-stage procedure to apply stress to the tested transistor DUT, simulating the stress encountered by the tested transistor DUT in actual applications and enabling accurate measurement of the dynamic on-resistance of the tested transistor DUT.

The first switch S1, the second switch S2, and the third switch S3 may be transistors or other types of switch components. For example, the first switch S1, the second switch S2, the third switch S3 and the tested transistor may be N-channel enhancement-mode MOSFETs as shown in FIG. 1, or in practice, may be replaced with other types of transistors. When the transistor is a field-effect transistor, the first terminal, the second terminal, and the control terminal described herein are a drain terminal, a source terminal, and a gate terminal, respectively.

A first terminal of the first switch S1 is connected to a first discharge node.

A second terminal of the first switch S1 is connected to a first terminal of the second switch S2. A first node between the second terminal of the first switch S1 and the first terminal of the second switch S2 is connected to a first terminal of an inductor L.

A first terminal of the third switch S3 is connected to a second discharge node.

A second terminal of the third switch S3 is connected to a first terminal of the tested transistor DUT. A second node between the second terminal of the third switch S3 and the first terminal of the tested transistor DUT is connected to a second terminal of the inductor L.

A second terminal of the second switch S2 and a second terminal of the tested transistor DUT are connected to a reference potential terminal. The dynamic on-resistance measurement circuit 1000 of the present disclosure may optionally include an input power supply circuit 300. A first terminal of the input power supply circuit 300 is connected to the first terminal of the third switch S3, and a second terminal (such as a negative terminal) of the input power supply circuit 300 may be connected to the reference potential terminal.

To provide a controllable stress current for accurate measurement of the dynamic on-resistance of the tested transistor DUT under a predetermined stress condition, the dynamic on-resistance measurement circuit 1000 further includes an energy storage circuit 100. The energy storage circuit 100 is connected to a common power source VCC, and is connected between the first discharge node and the second discharge node. This configuration avoids total reliance on the common power source VCC, which may fail to instantaneously supply a large current. Compared with the common power source VCC, the energy storage circuit 100 instantaneously supplies the larger current for applying stress to the tested transistor DUT. When the energy storage circuit 100 discharges, a discharge loop is formed, in which the current gradually increases to a specified stress current value, thereby controlling a rising rate of a stress voltage applied to the tested transistor DUT such that the stress voltage smoothly rises, so as to prevent surge waves from being generated.

The dynamic on-resistance measurement circuit 1000 of the present disclosure may further include a control circuit 200. The control circuit 200 is configured to control conduction states of a plurality of switch components (including the first switch S1, the second switch S2, and the third switch S3 as shown in FIG. 1). The control circuit 200 is connected to a control terminal of each of the plurality of switch components and a control terminal of the tested transistor DUT. In practice, the control circuit 200 described herein may be replaced by an external control circuit.

The control circuit 200 switches the switch components and the tested transistor DUT between an on state and an off state to control their operating states, thereby applying a stress voltage across the first terminal (such as a drain terminal) and the second terminal (such as a source terminal) of the tested transistor DUT.

Under the predetermined stress condition applied to the tested transistor DUT, the dynamic on-resistance measurement circuit 1000 of the present disclosure accurately measures the dynamic on-resistance of the tested transistor DUT (such as the Group III–V field-effect transistor), thereby reflecting conduction characteristics of the tested transistor DUT in a real operating environment. In this manner, a transient on-resistance of the tested transistor DUT that varies with bias voltages over time can be captured for reliable power loss analysis, efficiency evaluation, and component lifetime assessment, thereby meeting the requirements of high-efficiency power conversion and reliability.

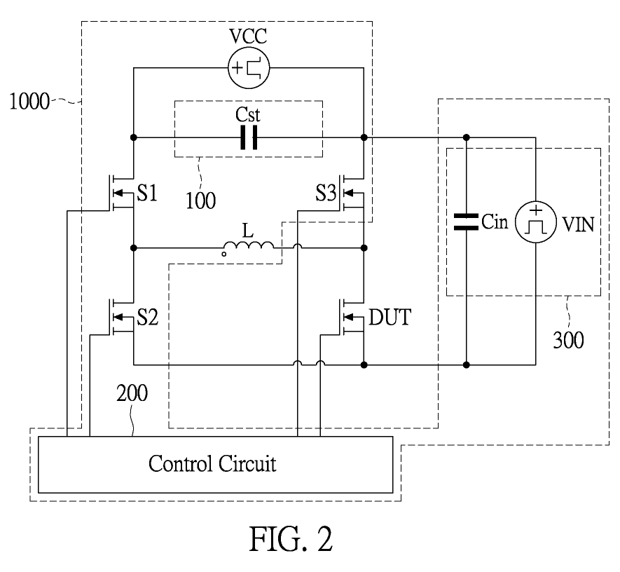

Reference is made to FIG. 2, which is a circuit diagram of a dynamic on-resistance measurement circuit according to a second embodiment of the present disclosure. Descriptions of the second embodiment that are the same as the descriptions of the first embodiment are not repeated herein.

In the second embodiment, for example, the energy storage circuit 100 may include an energy storage capacitor Cst. In practice, the energy storage circuit 100 may further include additional capacitors, or other energy storage components having an energy storing function or other functions, which may be connected in series with the energy storage capacitor Cst.

The energy storage capacitor Cst is connected in parallel with the common power source VCC. The energy storage capacitor Cst is connected between the first terminal of the first switch S1 and the first terminal of the third switch S3. That is, the energy storage capacitor Cst is connected between the first discharge node and the second discharge node.

A first terminal of the energy storage capacitor Cst is connected to a first terminal (such as a positive terminal) of the common power source VCC, and is connected to the first terminal of the first switch S1 through the first discharge node. A second terminal of the energy storage capacitor Cst is connected to a second terminal (such as a negative terminal) of the common power source VCC, and is connected to the second terminal of the third switch S3 through the second discharge node.

In the dynamic on-resistance measurement circuit 1000 of the present disclosure, the configuration of the energy storage capacitor Cst and the common power source VCC mainly serves the same purpose as that described for the energy storage circuit 100 above, that is, to provide a transient large current and form a controllable discharge loop, such that a stress current applied to the tested transistor DUT smoothly rises to a predetermined value.

In addition to the combined configuration of the energy storage capacitor Cst and the common power source VCC, the input power supply circuit 300 of the dynamic on-resistance measurement circuit 1000 of the present disclosure may include an input capacitor Cin and an input power source VIN. A first terminal of the input capacitor Cin is connected to the first terminal of the third switch S3. A second terminal of the input capacitor Cin is connected to the second terminal of the tested transistor DUT and the second terminal of the second switch S2.

The input power source VIN is connected in parallel with the input capacitor Cin. A first terminal (such as a positive terminal) of the input power source VIN is connected to the first terminal of the input capacitor Cin. A second terminal (such as a negative terminal) of the input power source VIN is connected to the second terminal of the input capacitor Cin. The input power source VIN supplies an input current to the input capacitor Cin to charge the input capacitor Cin to an input voltage, and supplies the input voltage of the input capacitor Cin is discharges to the first terminal of the third switch S3.

In the dynamic on-resistance measurement circuit 1000 of the present disclosure, the input capacitor Cin and the input power source VIN form another combined configuration, the main purpose of which is to supplement and coordinate the biasing and voltage stabilization. Specifically, the input capacitor Cin maintains stability of a voltage at a measurement node between the first terminal of the third switch S3 and the second terminal of the tested transistor DUT, ensuring accuracy of a voltage Vds between the first terminal (such as the drain terminal) and the second terminal (such as the source terminal) of the tested transistor DUT during stress application and measurement, and buffers transient charges during switching transitions, thereby preventing measurement errors caused by fluctuations of the voltage at the measurement node. Meanwhile, the input capacitor Cin and the input power source VIN also provide a stable voltage to the first terminal of the third switch S3, such that the third switch S3 can be reliably turned on to form a precisely controlled stress current loop.

By assigning different functions to the two sets of capacitors and power sources, the dynamic on-resistance measurement circuit 1000 of the present disclosure is able to simultaneously ensure bias stability of the tested transistor DUT, positive power supply for the third switch S3, and controllability of the stress current in the measurement procedure, thereby ensuring measurement accuracy of the dynamic on-resistance of the tested transistor DUT.

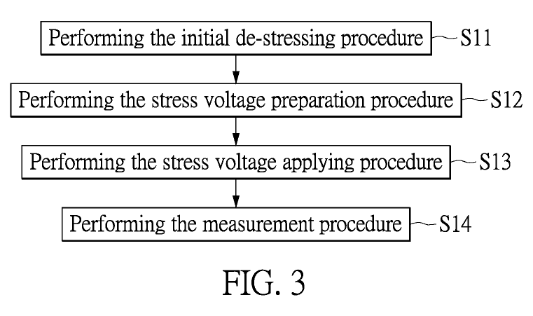

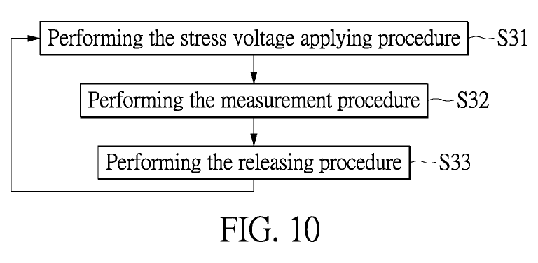

The dynamic on-resistance measurement circuit 1000 shown in FIGS. 1 and 2 is able to perform various measurement operations. Two types of measurement operations are exemplified herein, which are a single measurement operation (also referred to as a single-pulse measurement operation) as shown in FIGS. 3 to 9, and a continuous measurement operation as shown in FIGS. 10 to 14, which are described in detail below.

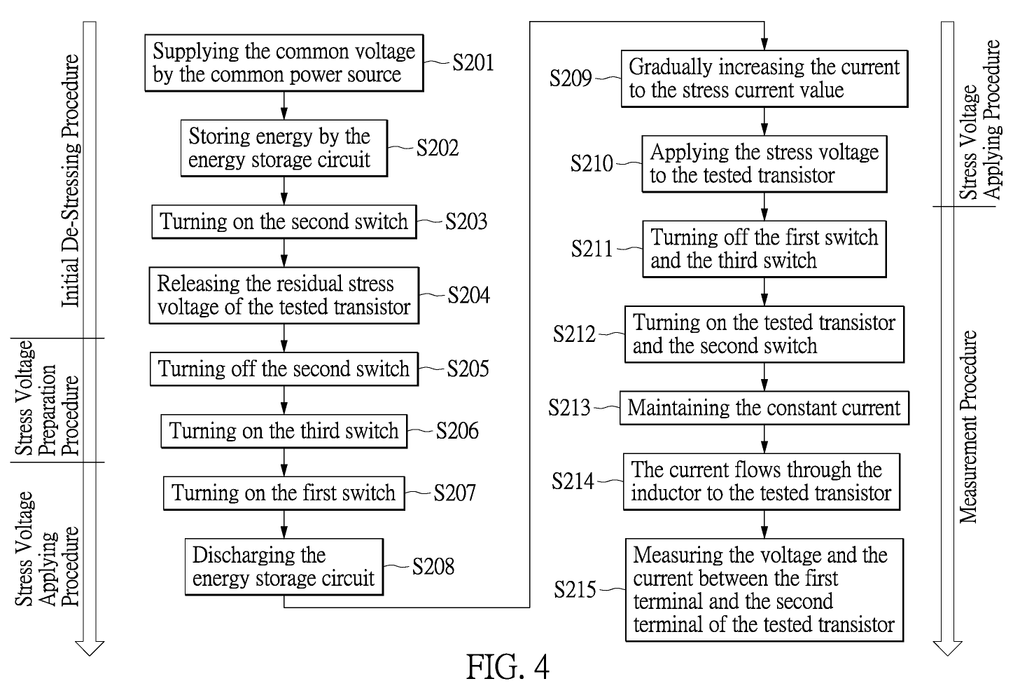

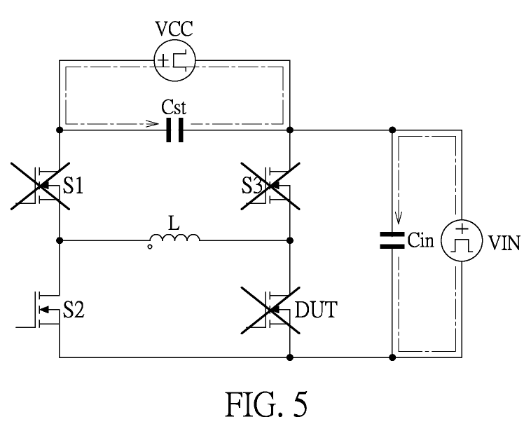

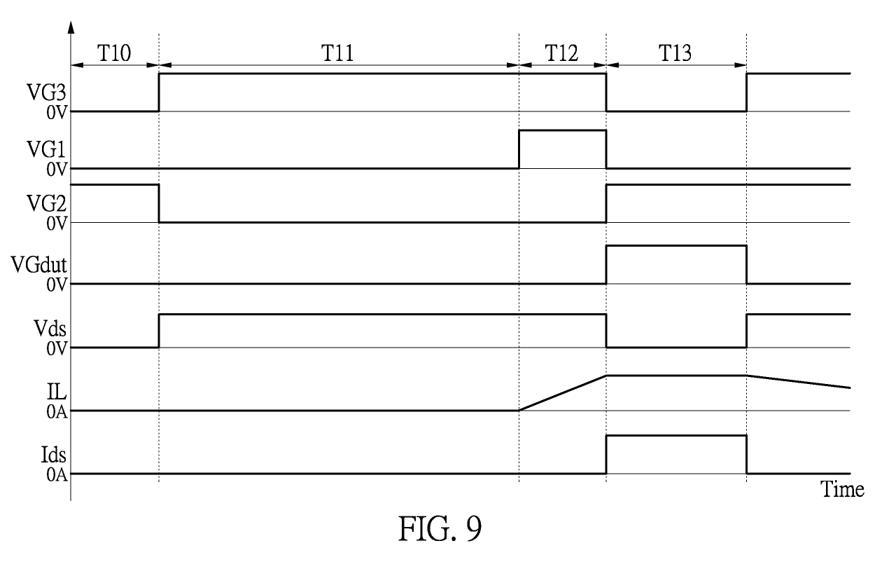

Reference is made to FIGS. 1 to 9, in which FIG. 1 is a circuit diagram of a dynamic on-resistance measurement circuit according to a first embodiment of the present disclosure , FIG. 2 is a circuit diagram of a dynamic on-resistance measurement circuit according to a second embodiment of the present disclosure, FIG. 3 is a flowchart diagram of a multi-stage procedure included in the single measurement operation of the dynamic on-resistance measurement circuit according to the first and second embodiments of the present disclosure, FIG. 4 is a flowchart diagram of specific processes in the multi-stage procedure included in the single measurement operation performed by the dynamic on-resistance measurement circuit according to the first and second embodiments of the present disclosure, FIGS. 5 to 8 are schematic diagrams of switching of a plurality of switch components of the dynamic on-resistance measurement circuit according to the second embodiment of the present disclosure, and FIG. 9 is a waveform diagram of a plurality of signals of the dynamic on-resistance measurement circuit according to the first and second embodiments of the present disclosure.

In the single measurement operation, the control circuit 200 of the dynamic on-resistance measurement circuit 1000 shown in FIGS. 1 and 2 sequentially performs an initial de-stressing procedure (in process S11 of FIG. 3), a stress voltage preparation procedure (in process S12 of FIG. 3), a stress voltage applying procedure (in process S13 of FIG. 3), a measurement procedure (in process S14 of FIG. 3), a first releasing procedure, and a second releasing procedure. In practice, the stress voltage preparation procedure, the first releasing procedure, the second releasing procedure, or a combination thereof may be selectively omitted.

In FIG. 2, the initial de-stressing procedure of process S11 includes processes S201 to S204 shown in FIG. 3, the stress voltage preparation procedure of process S12 includes processes S205 and S206 shown in FIG. 3, the stress voltage applying procedure of process S13 includes processes S207 to S210 shown in FIG. 3, and the measurement procedure includes processes S211 to S215 shown in FIG. 3 , which are described in detail as follows.

In the initial de-stressing procedure (in process S11 of FIG. 3), the common power source VCC (such as a voltage source or a current source) supplies a common current or a common voltage as shown in FIG. 5 (in process S201 of FIG. 4) to the energy storage circuit 100 for storing energy (in process S202 of FIG. 4), so as to charge the energy storage circuit 100 to have a voltage being equal to the common voltage for use in applying stress in the subsequent stress voltage applying procedure.

To ensure that the tested device (DUT) is in a stable and consistent initial state before measurement, the dynamic on-resistance measurement circuit 1000 of the present disclosure performs the initial de-stressing procedure (in process S11 of FIG. 3) before measurement, so as to eliminate residual voltage stress accumulated in the tested transistor DUT on a previous operation or measurement procedure. By removing such residual stress, its influence on voltage distribution and conduction characteristics in a subsequent stress applying stage can be prevented, thereby ensuring accuracy and repeatability of a measurement result. This also reduces measurement errors of the dynamic on-resistance caused by residual stress, which is particularly important for a Group III–V semiconductor component having high-frequency and high-speed switching characteristics.

Specifically, in the initial de-stressing procedure (in process S11 of FIG. 3), as shown in FIG. 5, the control circuit 200 only turns on the second switch S2 (in process S203 of FIG. 4), and turns off the first switch S1, the third switch S3, and the tested transistor DUT, such that the residual stress voltage of the tested transistor DUT is released through the second switch S2 (in process S204 of FIG. 4). This operation provides a controlled discharge path, such that a voltage release rate is controllable, thereby preventing redistribution of carriers inside the tested transistor DUT from being caused by abrupt current variation.

As shown in FIG. 9, within an initial de-stressing time interval T10, the initial de-stressing procedure is performed. In the initial de-stressing procedure, the control circuit 200 outputs a control signal VG2 at a high voltage level to the control terminal (such as a gate terminal) of the second switch S2 to turn on the second switch S2. In addition, in the initial de-stressing procedure, the control circuit 200 outputs control signals VG3, VG1, VGdut at a low voltage level respectively to the control terminal of the third switch S3, the control terminal of the first switch S1 and the control terminal of the tested transistor DUT, to turn off the third switch S3, the first switch S1 and the tested transistor DUT.

In the initial de-stressing procedure (in process S11 of FIG. 3), the control circuit 200 continually turns off the tested transistor DUT in order to prevent conduction current from interfering with the discharge path or causing redistribution of internal carriers during release of a residual voltage, which affects electrical stability of the tested transistor DUT. By continually turning off, the voltage Vds of the tested transistor DUT is reduced to zero, such that the residual voltage is completely released through a controlled path. As a result, initial conditions for subsequently applying the stress voltage are stable and controllable, thereby preventing adverse impact on subsequent measurement results. This approach improves measurement repeatability of the tested transistor DUT, and is particularly important for the tested transistor DUT made of wide bandgap materials such as GaN and SiC.

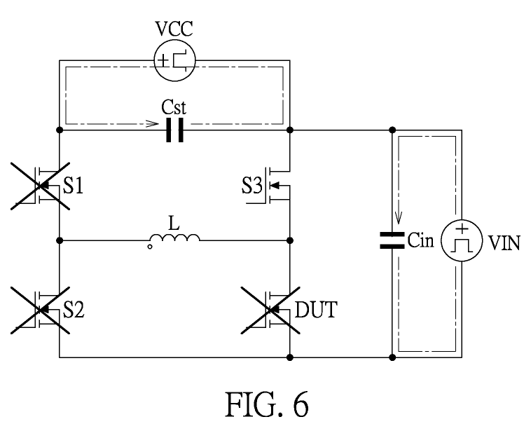

After completing the initial de-stressing procedure (in process S11 of FIG. 3) described above, the stress voltage preparation procedure (in process S12 of FIG. 3) is then performed. As shown in FIG. 6, in the stress voltage preparation procedure, the control circuit 200 turns off the second switch S2 (in process S205 of FIG. 4) and turns on the third switch S3 (in process S206 of FIG. 4). In this manner, when the third switch S3 is turned on in the subsequent stress voltage applying procedure, a discharge loop can be directly formed. If the third switch S3 is not turned on in advance, the energy storage circuit 100 and the tested transistor DUT may be electrically disconnected, such that a complete discharge loop cannot be immediately formed at the moment of stress application, thereby affecting establishment and stability of the stress current.

Therefore, the third switch S3 is turned on in the stress voltage preparation procedure as shown in FIG. 6 and may be regarded as a path preparation procedure for a subsequent stress voltage applying stage, such that when the first switch S1 is turned on in the subsequent stress voltage applying procedure (in process S13 of FIG. 3), the energy stored in the energy storage circuit 100 can immediately flow through the inductor L and the tested transistor DUT to form the stable discharge path. In this manner, transient overvoltage or current spikes that may cause measurement errors can be prevented, ensuring that the stress voltage is stably established at an initial stage of application, thereby improving continuity of the discharge loop and repeatability of the stress applying procedure. This stress applying procedure is particularly critical for the tested transistor DUT having high-voltage and high-speed switching characteristics, and is able to reduce transient errors in measurement of the dynamic on-resistance.

In other words, the third switch S3 being turned on in a preparation stage is to ensure that a connection state between the energy storage circuit 100 and the discharge loop is stable, so as to establish the complete discharge path for the subsequent stress voltage applying stage, ensuring that stored energy is smoothly and controllably applied to the tested transistor DUT. This further improves electrical stability and helps reduce waveform distortion caused by switching delay or incomplete conduction.

As shown in FIG. 9, within a stress voltage preparation time interval T11, the stress voltage preparation procedure is performed. In the stress voltage preparation procedure, the control signal VG2 received by the control terminal (such as the gate terminal) of the second switch S2 transits from the high voltage level to the low voltage level to turn off the second switch S2, and the control signal VG3 received by the control terminal of the third switch S3 transits from the low voltage level to the high voltage level to turn on the third switch S3. As a result, the voltage Vds between the first terminal (such as the drain terminal) and the second terminal (such as the source terminal) of the tested transistor DUT increases to a stress voltage level due to application of the stress voltage.

It should be understood that, the stress voltage preparation procedure may be selectively performed according to actual application requirements. If the discharge path has been kept stable in a previous operation cycle, or if a connection between the energy storage circuit 100 and the first and second discharge nodes has not been interrupted, the stress voltage preparation procedure may be omitted to simplify a control flow. However, when it is necessary to ensure stable formation of the discharge loop or to prevent electrical discontinuity from being caused by delay of a switch component, performing the stress voltage preparation procedure can effectively improve stability and repeatability of the subsequent stress applying stage.

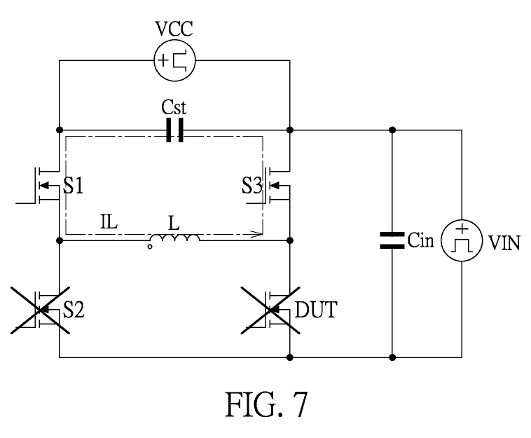

After the stress voltage preparation procedure is performed as described above (in process S12 of FIG. 3), the stress voltage applying procedure (in process S13 of FIG. 3) is then performed. As shown in FIG. 7, the control circuit 200 continually turns on the third switch S3 and turns on the first switch S1 (in process S207 of FIG. 4), such that the energy storage circuit 100 discharges (in process S208 of FIG. 4). A discharge current IL of the energy storage circuit 100 sequentially flows through the first switch S1, the inductor L, and the third switch S3 to form a discharge loop, such that the current IL flowing through the inductor L gradually increases to a desired stress current value (in process S209 of FIG. 4), thereby applying the stress voltage to the first terminal (such as the drain terminal) and the second terminal (such as the source terminal) of the tested transistor DUT (in process S210 of FIG. 4).

As shown in FIG. 9, within the stress voltage applying time interval T12, the stress voltage applying procedure is performed. In the stress voltage applying procedure, the control signal VG3 received by the control terminal of the third switch S3 remains at a high voltage level to continually turn on the third switch S3, and the control signal VG1 received by the control terminal of the first switch S1 transits from the low voltage level to the high voltage level to turn on the first switch S1.

A main purpose of applying the stress voltage in the stress voltage applying procedure is to simulate behavior of the tested transistor DUT under an actual high-voltage blocking operating state. Applying the predetermined stress voltage can induce a trapping effect inside the tested transistor DUT. In particular, for wide bandgap semiconductor materials such as GaN and SiC, electrons or holes may be trapped under the high voltage Vds of the tested transistor DUT, resulting in an increase in the dynamic on-resistance of the tested transistor DUT. By applying the same stress voltage before measurement, initial conditions of the tested transistor DUT can be unified, thereby preventing influence on accuracy and repeatability of subsequent measurement results due to inconsistent states.

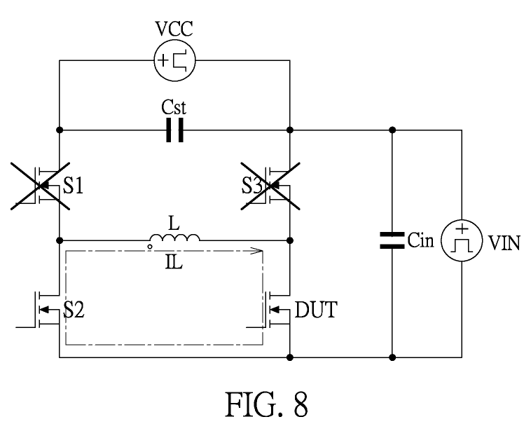

After the stress applying procedure is completed, the measurement procedure (in process S14 of FIG. 3) is performed. In the measurement procedure, as shown in FIG. 8, the control circuit 200 turns off the first switch S1 and the third switch S3 (in process S211 of FIG. 4), and turns on the tested transistor DUT and the second switch S2 (in process S212 of FIG. 4), such that the tested transistor DUT, the inductor L, and the second switch S2 form a closed loop. At this time, since the first switch S1 and the third switch S3 have been switched from the on state to the off state, the energy storage circuit 100 stops supplying power to the inductor L. The current IL of the inductor L no longer increases, and due to characteristics of the inductor L resisting abrupt current changes, the current IL varies smoothly. As shown in FIG. 9, during the measurement time interval T13, the current IL is maintained as the constant current (in process S213 of FIG. 4) and flows from the inductor L through the tested transistor DUT (in process S214 of FIG. 4). When the constant current IL flows through the tested transistor DUT, the control circuit 200 measures the voltage Vds between the first terminal (such as the drain terminal) and the second terminal (such as the source terminal) of the tested transistor DUT and a value of the constant current IL (in process S215 of FIG. 4), and calculates the dynamic on-resistance of the tested transistor DUT based on the measured voltage Vds and the measured current value.

Since the current is constant during the process of measuring the dynamic on-resistance of the tested transistor DUT, measurement errors caused by current fluctuation are prevented, ensuring that the tested transistor DUT is subjected to consistent carrier flow conditions during the measurement time interval T13. This stabilizes a trapping effect and improves the accuracy of the measurement of the dynamic on-resistance of the tested transistor DUT.

A main technical feature of the present disclosure is that, in the above single measurement operation, the dynamic on-resistance measurement circuit 1000 applies the stress to the tested transistor DUT only once and measures the dynamic on-resistance of the tested transistor DUT under such stress. Since emphasis is placed on the measurement procedure and preparatory operations, post-measurement procedures, such as a release operation, may be determined according to actual requirements.

For ease of practical implementation, the release operation performed by the dynamic on-resistance measurement circuit 1000 in the single measurement operation may include a first releasing procedure, a second releasing procedure, or a combination thereof. After the measurement procedure, in the first releasing procedure, the control circuit 200 turns off the tested transistor DUT and turns on the third switch S3 to reduce the current IL to a low current level. Then, the second releasing procedure may be performed, in which the tested transistor DUT is turned on so as to reduce the current IL to zero.

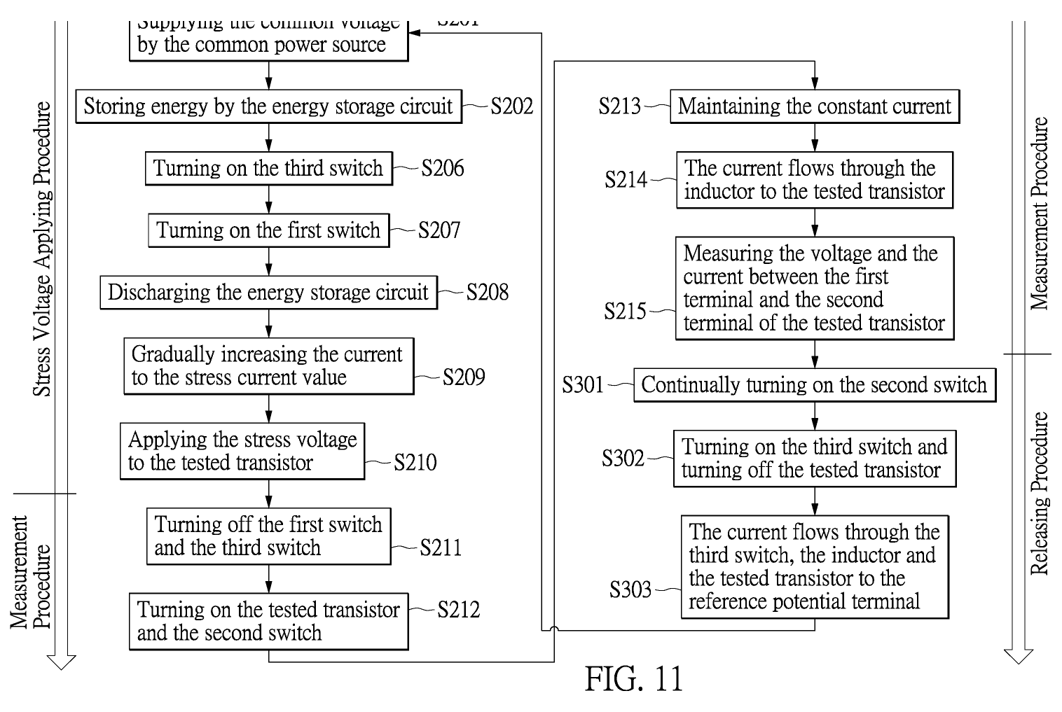

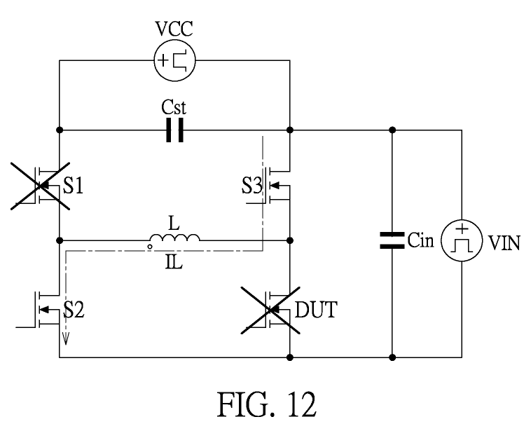

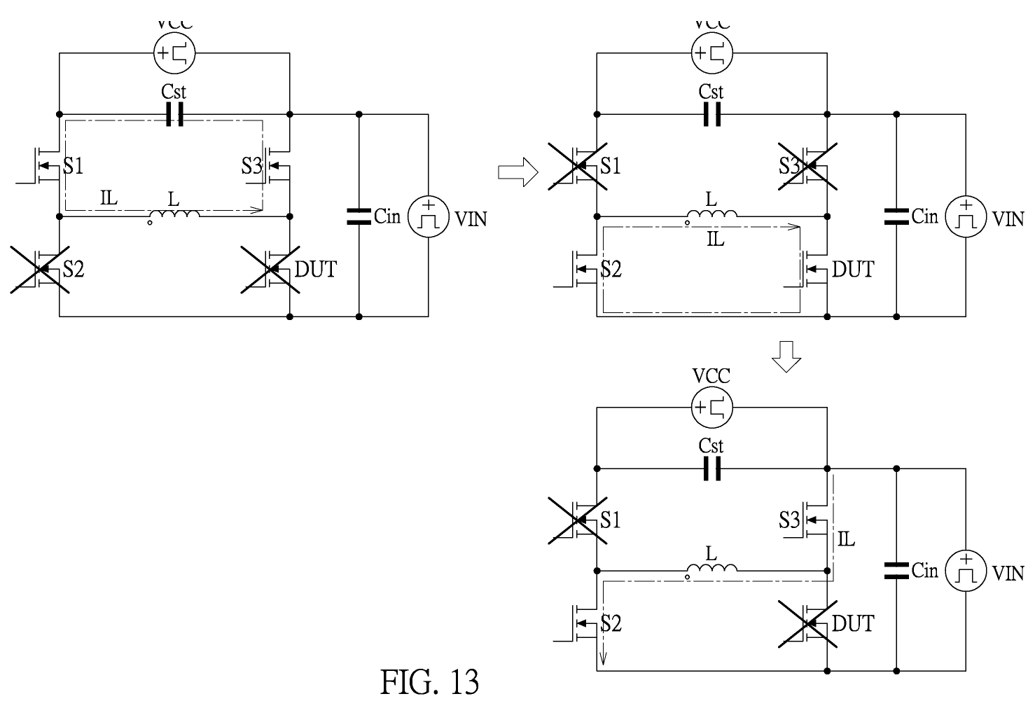

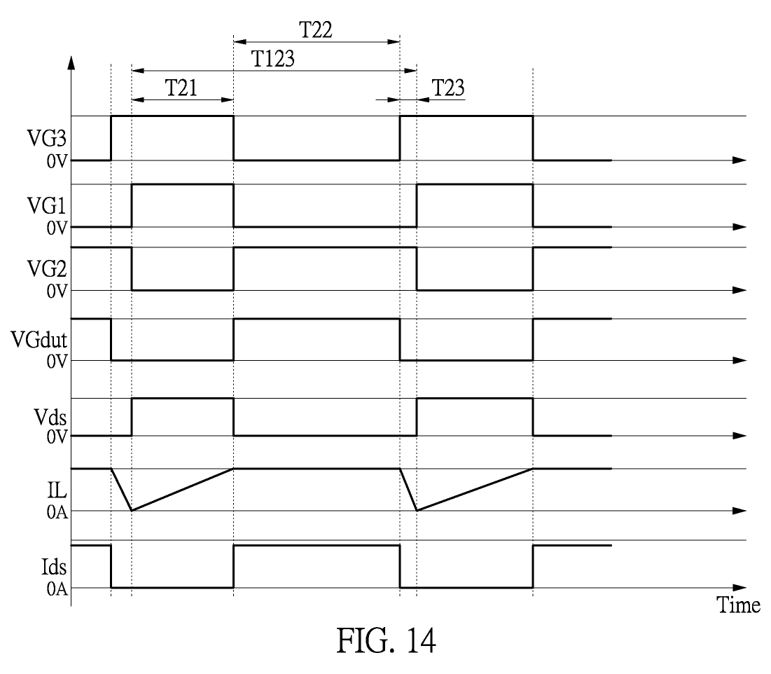

Reference is made to FIGS. 10 to 14, in which FIG. 10 is a flowchart diagram of a multi-stage procedure included in a continuous measurement operation performed by the dynamic on-resistance measurement circuit according to the first and second embodiments of the present disclosure, FIG. 11 is a flowchart diagram of specific processes in the multi-stage procedure included in the continuous measurement operation, FIGS. 12 and 13 are schematic diagrams of switching of a plurality of switch components of the dynamic on-resistance measurement circuit according to the second embodiment of the present disclosure, and FIG. 14 is a waveform diagram of a plurality of signals of the dynamic on-resistance measurement circuit according to the second embodiment of the present disclosure.

The dynamic on-resistance measurement circuit 1000 may perform the above single measurement operation, or the following continuous measurement operation. In the multi-stage procedure included in the continuous measurement operation, as shown in FIG. 1 or FIG. 2, the dynamic on-resistance measurement circuit 1000 sequentially performs a stress voltage applying procedure (in process S31 of FIG. 10), a measurement procedure (in process S32 of FIG. 10), and a releasing procedure (in process S33 of FIG. 10).

The stress voltage applying procedure of process S31 shown in FIG. 10 includes processes S201, S202, and S206 to S210 shown in FIG. 11. The measurement procedure of process S32 shown in FIG. 10 includes processes S211 to S215 s shown in FIG. 11 . The releasing procedure of process S33 shown in FIG. 10includes processes S401 to S403 shown in FIG. 11. Contents of these processes have been described above, and thus are not repeated herein.

It is worth noting that, the single measurement operation and the continuous measurement operation are the same in basic circuit structure and switching logic. Both form three stages of rising, constant recirculation, and falling of the inductor current IL by controlling the on-state and the off-state of the first switch S1, the second switch S2, and the third switch S3. However, the two operations differ significantly in operation flow and timing relationship.

In a single measurement mode, the single measurement operation is performed once, in which the initial de-stressing procedure, the stress voltage applying procedure, the measurement procedure (and the releasing procedure) are each performed once. Before each measurement, the residual stress of the tested transistor DUT needs to be removed by turning on the third switch S3 and turning off other switches, such that the voltage Vds across the first and second terminals of the tested transistor DUT is reduced to zero, thereby clearing charge traps or parasitic voltages that may remain from a previous operation and ensuring that each measurement starts from an unstressed initial state. In this manner, unintended stress accumulation can be prevented, thereby improving accuracy of the dynamic on-resistance under a single pulse.

In contrast, in a continuous measurement mode, the continuous measurement operation is cyclically performed multiple times. In each cycle, the stress voltage applying procedure, the measurement procedure, and the releasing procedure are performed. As shown in FIG. 14, the continuous measurement operation is performed once within an operation cycle T123, in which the stress voltage applying procedure is performed within a stress voltage applying time interval T21, the measurement procedure is performed within a measurement time interval T22, and the releasing procedure is performed within a releasing time interval T23.

In the releasing procedure of the continuous measurement operation, the tested transistor DUT is turned off and the first switch S1 is turned on, such that the inductor current IL naturally decreases to near zero. When the current IL approaches or reaches zero, the second switch S2 is turned on again to enter a next cycle of the stress applying stage. Since this cyclic operation automatically returns the current IL and the voltage to a low-energy state, there is no need to additionally remove residual stress of the tested transistor DUT (that is, processes S203 to S205 in FIG. 4 are omitted), thereby ensuring stable initial conditions for each measurement. In the multi-stage procedure included in the continuous measurement operation, similar to the above single measurement operation, when performing the on-resistance measurement procedure of the tested transistor DUT, a stress current Ids of the tested transistor DUT is maintained at a constant current value during the measurement time interval T22 as shown in FIG. 14.

In other words, due to a self-cycling characteristic of the dynamic on-resistance measurement circuit 1000 in the continuous measurement operation, there is no need to additionally perform the initial de-stressing procedure. This not only maintains continuity and efficiency of measurement, but also simulates an actual operating state of a power transistor under high-speed repetitive switching. The continuous measurement operation can evaluate stability, accumulation effects, and long-term reliability of the dynamic on-resistance of the tested transistor DUT under continuous stress.

In the continuous measurement operation, when the measurement procedure has been completed and the releasing procedure is performed, as shown in FIGS. 12 and 13, the control circuit 200 continually turns on the second switch S2 (in process S401 of FIG. 11), and turns on the third switch S3 and turns off the tested transistor DUT (in process S402 of FIG. 11), such that the current IL flows through the third switch S3, the inductor L, and the tested transistor DUT to the reference potential terminal (that is, the negative terminal of the input power supply circuit 300 in FIG. 1 or the input power source VIN in FIG. 2) to release electrical energy (in process S403 of FIG. 11).

The control circuit 200 may, in the continuous measurement operation, sequentially perform the stress voltage applying procedure, the stress voltage measurement procedure and the stress voltage releasing procedure once to obtain one the dynamic on-resistance of the tested transistor DUT. After the control circuit 200 performs the continuous measurement operation multiple times, the control circuit 200 obtains a plurality of pieces of dynamic on-resistance, thereby accurately evaluating variation of the dynamic on-resistance of the tested transistor DUT under continuous stress.

The single measurement operation is suitable for observing transient dynamic on-resistance under a single stress, and focuses on consistency and repeatability of measurement conditions. The continuous measurement operation can simulate an operating environment of continuous switching of a switch component in an actual circuit, reflect variation of conduction characteristics of the tested transistor DUT under repeated stress, and improve measurement sensitivity and data stability.

In summary, the present disclosure provides the dynamic on-resistance measurement circuit. In the dynamic on-resistance measurement circuit of the present disclosure, through coordinated operation of the switch components, the energy storage circuit and the control circuit, precisely controls timing and conditions for stress application, release, and measurement of the tested transistor (particularly the Group III–V field-effect transistor). Since conduction characteristics of the Group III–V field-effect transistor are easily affected by surface and interface trap charges, its dynamic on-resistance varies with bias and time conditions. If the measurement procedure lacks precise control, trapping effects interferes with measurement results and cause instability or inaccuracy. The dynamic on-resistance measurement circuit of the present disclosure employs an improved hardware circuit to execute an innovative procedure, such that operating conditions of each measurement stage can be precisely set and controlled, thereby effectively suppressing influence of trapping effects on measurement and ensuring that the dynamic on-resistance truly reflects characteristics of the tested transistor.

In the single measurement operation, the dynamic on-resistance measurement circuit of the present disclosure further releases residual charges accumulated in the tested transistor through the initial de-stressing procedure. Since each single measurement is independently performed, if the residual stress is not removed in advance, the trap charges remaining from the previous operation may interfere with subsequent stress application and measurement results, causing unstable initial conditions. The initial de-stressing procedure ensures that the single measurement operation is performed on a stable baseline, thereby improving measurement accuracy and comparability of the dynamic on-resistance.

In addition, in the dynamic on-resistance measurement circuit of the present disclosure, the energy storage circuit stores energy supplied by the common power source and releases the energy in a controllable manner, so as to provide a sufficient stress current to simulate actual stress conditions. In the measurement procedure after the stress is applied, the stress current flows sequentially through the inductor and the tested transistor. By virtue of the inductive characteristics, the current is maintained at the constant value, thereby preventing measurement errors from being caused by current fluctuations and ensuring that each measurement of the tested transistor is performed under consistent energy conditions, further improving the accuracy and repeatability of the measurement results.

Accordingly, the dynamic on-resistance measurement circuit of the present disclosure is capable of overcoming the problems in the relevant art that measurement conditions are difficult to adjust independently, blocking time cannot be precisely controlled, and measurement results are susceptible to interference, thereby making the dynamic characteristic evaluation of the Group III–V field-effect transistor more reliable and further enhancing the accuracy performance verification and reliability analysis of the power components.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A dynamic on-resistance measurement circuit, which is used for measuring a tested transistor, and comprising:
an energy storage circuit connected to a common power source and connected between a first discharge node and a second discharge node;
a plurality of switch components including a first switch, a second switch and a third switch, wherein a first terminal of the first switch is connected to the first discharge node, a first terminal of the third switch is connected to the second discharge node, a second terminal of the first switch is connected to a first terminal of the second switch and a first terminal of an inductor, a first terminal of the tested transistor is connected to a second terminal of the third switch and to a second terminal of the inductor, and a second terminal of the second switch and a second terminal of the tested transistor are connected to a reference potential terminal; and
a control circuit connected to a control terminal of each of the plurality of switch components, and configured to perform a single measurement operation including, sequentially:
in an initial de-stressing procedure, turning on only the second switch, such that a residual stress voltage of the tested transistor is released through the second switch;
in a stress voltage applying procedure, turning off the second switch and turning on the third switch and the first switch, such that a stress voltage is applied across the first terminal and the second terminal of the tested transistor; and
in a measurement procedure, turning off the first switch and the third switch and turning on the tested transistor and the second switch, measuring a voltage and a current between the first terminal and the second terminal of the tested transistor, and calculating a dynamic on-resistance of the tested transistor according to the voltage and the current.

2. The dynamic on-resistance measurement circuit according to claim 1, wherein, in the measurement procedure, the current is maintained at a stress current value to form a constant current.

3. The dynamic on-resistance measurement circuit according to claim 1, wherein the control circuit is further configured to:
perform a stress voltage preparation procedure by first turning on the third switch, after performing the initial de-stressing procedure and before the stress voltage applying procedure.

4. The dynamic on-resistance measurement circuit according to claim 1, wherein the control circuit is further configured to:
perform a first releasing procedure by turning off the tested transistor and turning on the third switch to reduce the current, after the measurement procedure is performed.

5. The dynamic on-resistance measurement circuit according to claim 4, wherein the control circuit is further configured to:
perform a second releasing procedure by turning on the tested transistor to reduce the current to zero, after the first releasing procedure is performed.

6. The dynamic on-resistance measurement circuit according to claim 1, wherein the energy storage circuit includes:
an energy storage capacitor connected between the first discharge node and the second discharge node and connected to the common power source.

7. The dynamic on-resistance measurement circuit according to claim 1, further comprising:
an input power supply circuit connected to the first terminal of the third switch, and configured to supply an input voltage to the first terminal of the third switch.

8. The dynamic on-resistance measurement circuit according to claim 7, wherein the input power supply circuit includes:
an input capacitor, wherein a first terminal of the input capacitor is connected to the first terminal of the third switch, and a second terminal of the input capacitor is connected to the second terminal of the tested transistor and the second terminal of the second switch; and
an input power source connected to the input capacitor and configured to supply input power to the input capacitor, wherein the capacitor is configured to store the input power and discharges to the first terminal of the third switch.

9. The dynamic on-resistance measurement circuit according to claim 1, wherein the tested transistor is a III–V group field-effect transistor.

10. The dynamic on-resistance measurement circuit according to claim 1, wherein the tested transistor is a gallium nitride transistor, an aluminum nitride transistor, or an aluminum gallium nitride transistor.

11. A dynamic on-resistance measurement circuit, which is used for measuring a tested transistor, and comprising:
an energy storage circuit connected to a common power source and connected between a first discharge node and a second discharge node;
a plurality of switch components including a first switch, a second switch, and a third switch, wherein a first terminal of the first switch is connected to the first discharge node, a first terminal of the third switch is connected to the second discharge node, a second terminal of the first switch is connected to a first terminal of the second switch and a first terminal of an inductor, a first terminal of the tested transistor is connected to a second terminal of the third switch and a second terminal of the inductor, and a second terminal of the second switch and a second terminal of the tested transistor are connected to a reference potential terminal; and
a control circuit connected to the control terminal of each of the plurality of switch components, and configured to perform a continuous measurement operation multiple times, wherein the continuous measurement operation includes, sequentially:
in a stress voltage applying procedure, turning on the third switch and the first switch to apply a stress voltage across the first terminal and the second terminal of the tested transistor;
in a measurement procedure, turning off the third switch and the first switch and turning on the tested transistor and the second switch, measuring a voltage and a current between the first terminal and the second terminal of the tested transistor, and calculating a dynamic on-resistance of the tested transistor according to the voltage and the current; and
in a releasing procedure, continually turning on the second switch, turning on the third switch and turning off the tested transistor, such that the current flows through the third switch, the inductor, and the tested transistor to the reference potential terminal for releasing.

12. The dynamic on-resistance measurement circuit according to claim 11, wherein, in the continuous measurement operation, a duration of the releasing procedure is smaller than a duration of the measurement procedure.

13. The dynamic on-resistance measurement circuit according to claim 11, wherein, in the continuous measurement operation, a duration of the releasing procedure is smaller than a duration of the stress voltage applying procedure.

14. The dynamic on-resistance measurement circuit according to claim 11, wherein, in the measurement procedure, the current is maintained at a stress current value to form a constant current.

15. The dynamic on-resistance measurement circuit according to claim 11, wherein the energy storage circuit includes:
an energy storage capacitor connected between a first terminal of the first switch and the first terminal of the third switch, and connected to the common power source.

16. The dynamic on-resistance measurement circuit according to claim 11, further comprising:
an input power supply circuit configured to supply an input voltage to the first terminal of the third switch.

17. The dynamic on-resistance measurement circuit according to claim 16, wherein the input power supply circuit includes
an input capacitor, wherein a first terminal of the input capacitor is connected to the first terminal of the third switch, and a second terminal of the input capacitor is connected to the second terminal of the tested transistor and the second terminal of the second switch; and
an input power source connected to the input capacitor and configured to supply input power to the input capacitor, wherein the capacitor is configured to store the input power and discharges to the first terminal of the third switch.

18. The dynamic on-resistance measurement circuit according to claim 11, wherein the tested transistor is a III–V group field-effect transistor.

19. The dynamic on-resistance measurement circuit according to claim 11, wherein the tested transistor is a gallium nitride transistor, an aluminum nitride transistor, or an aluminum gallium nitride transistor.
